(19) United States
(12) Patent Application Publication
(10) Pub. No.: US 2026/0155164 A1
(43) Pub. Date: Jun. 4, 2026

(54) WORD LINE DRIVER SYSTEM FOR NON-VOLATILE MEMORY STRUCTURE

(71) Applicant: GlobalFoundries U.S. Inc., Malta, NY (US)

(72) Inventors: Ramesh Raghavan, Narsingi Hyderabad (IN); Dharmaraju Vasantada, Andhra Pradesh (IN); Amit Kumar Shukla, Bangalore (IN); Bipul C. Paul, Mechanicville, NY (US)

(21) Appl. No.: 18/965,063

(22) Filed: Dec. 2, 2024

(51) Int. Cl. G11C 11/16

(52) U.S. Cl. CPC G11C 11/1657; G11C 11/1673; G11C 11/1675

(57) ABSTRACT

Disclosed are a word line (WL) driver and a memory structure including a WL driver system with multiple WL drivers. The WL driver includes a write WL voltage (VWL) control node, a read VWL control node, and an output node. First and second transistors are connected in series between the write VWL control node and the output node. Third and fourth transistors are connected in parallel between the read VWL control node and the output node. The first, second, and third transistors are P-type field effect transistors (PFETs) and the fourth transistor is an N-type field effect transistor (NFET). Additional NFETs are connected between the output node and ground and, optionally, between the gate and source of the second transistor. All transistors are the same gate dielectric type.

### BACKGROUND

The present disclosure relates to non-volatile memory (NVM) structures and, more particularly, to embodiments of word line (WL) driver system and embodiments of an NVM structure including the WL driver system.

Typically, an NVM structure (e.g., a magnetic random access memory (MRAM) structure, a resistive random access memory (RRAM) structure, a phase change memory (PCM) structure, etc.) includes an array of NVM cells (also referred to herein as bit cells) arranged in columns and rows. The structure further includes bit line (BL)-source line (SL) pairs for the columns, respectively, and word lines (WLs) for the rows, respectively. Each NVM cell includes, for example, an access transistor (e.g., an N-type field effect transistor (NFET)) and a programmable resistor (e.g., a magnetic tunnel junction (MTJ)-type resistor or some other suitable type of programmable resistor, such as a resistive random access memory (RRAM)-type programmable resistor or a phase change memory (PCM)-type programmable resistor). Within each bit cell in a column, the access transistor and programmable resistor are electrically connected in series between the BL and SL of the BL-SL pair for that column. Within each bit cell in a row, the gate of the access transistor is electrically connected to the WL for that row.

Within the NVM structure, different memory operations, including both write and read operations, can be directed to a selected bit cell by applying operation-dependent biasing conditions on the WL, BL, and SL connected to the selected bit cell. A WL driver system, which includes WL drivers connected to the WLs, respectively, provides the word line voltage (VWL) employed for such memory operations. However, WL driver systems for NVM structures may be relatively complex because, for example, each WL driver includes a mixture of different types of transistors (e.g., P-type field effect transistors (PFETs) and N-type field effect transistors (NFETs) with a relatively thin gate dielectric layer, also referred to herein as standard gate dielectric (SG) transistors and PFETs and NFETs with a relatively thick gate dielectric layer, also referred to herein as extra gate dielectric (EG) transistors). Furthermore, such WL driver systems may consume a significant amount of chip area because, for example, each WL driver includes a relatively large number of transistors (e.g., over ten transistors, such as sixteen transistors). Finally, with such WL driver systems, WL load capacitance may be relatively high and the slew rate for charging a WL from 0.0 V to the operation-specific positive VWL may be significantly lower at the distal end of the WL (i.e., the end farthest from the WL driver) as compared to the proximal end of the WL (i.e., the end closes to the WL driver). For example, in some cases, it may take over 2 nanoseconds (ns) (e.g., ˜2.75 ns) longer for the distal end of the WL to charge to the VWL, thereby resulting in a significant cycle time loss (e.g., of >25%).

### SUMMARY

Disclosed herein are embodiments of a WL driver and embodiments of a non-volatile memory (NVM) structure including a WL driver system with multiple instances of the disclosed WL driver.

More specifically, disclosed herein are embodiments of a WL driver. The WL driver can include a first word line voltage (VWL) control node, a second VWL control node, and an output node. The WL driver can further include a first transistor and a second transistor connected in series between the first VWL control node and the output node. The WL driver can further include a third transistor and a fourth transistor connected in parallel between the second VWL control node and the output node. Additionally, within the WL driver, the first transistor, the second transistor and the third transistor can have a first type conductivity (e.g., P-type conductivity) and the fourth transistor can have a second type conductivity that is different from the first type conductivity (e.g., N-type conductivity).

In some embodiments, the WL driver can include a first word line voltage (VWL) control node connected to receive a write mode voltage signal, a second VWL control node connected to receive a read mode voltage signal, and an output node. The WL driver can further include a first transistor and a second transistor connected in series between the first VWL control node and the output node. The WL driver can further include a third transistor and a fourth transistor connected in parallel between the second VWL control node and the output node. The WL driver can further include a fifth transistor and a sixth transistor connected in series between the output node and ground. The WL driver can further include a seventh transistor connected in parallel with the sixth transistor between the fifth transistor and ground and an eighth transistor connected between a gate of the second transistor and a junction between the first transistor and the second transistor. Additionally, within this WL driver, gates of the first transistor and the eighth transistor can be connected, the first transistor, the second transistor, and the third transistor can be P-type field effect transistors, and the fourth transistor, the fifth transistor, the sixth transistor, the seventh transistor, and the eighth transistor can be N-type field effect transistors.

Also disclosed herein are embodiments of a NVM structure. The NVM structure can include an array of bit cells in columns and rows, word lines (WLs) for the rows, respectively, and a WL driver system. The WL driver system can include at least one WL driver connected to each of the WLs. Each WL driver can include a first word line voltage (VWL) control node; a second VWL control node; and an output node connected to an end of a WL. Each WL driver can further include a first transistor and a second transistor connected in series between the first VWL control node and the output node. Each WL driver can further include a third transistor and a fourth transistor connected in parallel between the second VWL control node and the output node. Within each WL driver, the first transistor, the second transistor, and the third transistor can have a first type conductivity (e.g., P-type conductivity) and the fourth transistor can have a second type conductivity that is different from the first type conductivity (e.g., N-type conductivity).

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1A is a schematic diagram illustrating disclosed embodiments of a WL driver;

FIG. 1B is a cross-section diagram illustrating one example of a dual-gated transistor that could be included in the WL driver of FIG. 1A;

FIG. 1C is a table illustrating examples of bias conditions that could be employed in the WL driver during different modes;

FIG. 2A is a schematic diagram illustrating disclosed embodiments of a NVM structure;

FIG. 2B is a table illustrating different sets of signals to be received by a pair of WL drivers for a row as a function of different control signals; and

FIG. 2C is a block diagram illustrating an example of a portion of control logic incorporated into the WL driver system in the NVM structure of FIG. 2A.

### DETAILED DESCRIPTION

As mentioned above, within a typical NVM structure (e.g., an MRAM structure, etc.), different memory operations, including both write and read operations, can be directed to a selected bit cell by applying operation-dependent biasing conditions on the WL, BL, and SL connected to the selected bit cell. A WL driver system, which includes WL drivers connected to the WLs, respectively, provides the word line voltage (VWL) employed for such memory operations. However, WL driver systems for NVM structures may be relatively complex because, for example, each WL driver includes a mixture of different types of transistors (e.g., P-type field effect transistors (PFETs) and N-type field effect transistors (NFETs) with a relatively thin gate dielectric layer, also referred to herein as standard gate dielectric (SG) transistors and PFETs and NFETs with a relatively thick gate dielectric layer, also referred to herein as extra gate dielectric (EG) transistors). Furthermore, such WL driver systems may consume a significant amount of chip area because, for example, each WL driver includes a relatively large number of transistors (e.g., over ten transistors, such as sixteen transistors). Finally, with such WL driver systems, WL load capacitance may be relatively high and the slew rate for charging a WL from 0.0 V to the operation-specific positive VWL may be significantly lower at the distal end of the WL (i.e., the end farthest from the WL driver) as compared to the proximal end of the WL (i.e., the end closes to the WL driver). For example, in some cases, it could take over 2 nanoseconds (ns) (e.g., ˜2.75 ns) longer for the distal end of the WL to charge to the VWL, thereby resulting in a significant cycle time loss (e.g., of >25%).

In view of the foregoing, disclosed herein are embodiments of a WL driver for a NVM structure (e.g., for an MRAM structure). The WL driver can include a first word line voltage (VWL) control node (also referred to herein as a write VWL control node), a second VWL control node (also referred to herein as a read VWL control node), and an output node. The WL driver can further include a first transistor and a second transistor connected in series between the first VWL control node and the output node. The WL driver can also include a third transistor and a fourth transistor connected in parallel between the second VWL control node and the output node. The first transistor, the second transistor and the third transistor can have a first type conductivity (e.g., they can be P-type field effect transistors (PFETs)) and the fourth transistor can have a second type conductivity different from the first type conductivity (e.g., it can be an N-type field effect transistor (NFET)). Additional transistors (e.g., additional NFETs) can be connected between the output node and ground and, optionally, between the gate and source of the second transistor such that the WL driver has a maximum number of eight transistor. Furthermore, all of these transistors can be SG transistors. In operation, voltage levels on the first VWL control node and the second VWL control node can be mode-dependent. Additionally, the first transistor, the third transistor and the fourth transistor can be controlled by different mode select signals. By incorporating the fourth transistor (an NFET) in parallel with the third transistor (a PFET) between the second VWL control node and the output node, drive current is improved in the read mode and, thus, slew is improved (i.e., speed at which the WL is charged during the read mode is increased). Thus, performance is improved. Optionally, at least the third transistor and/or the fourth transistor could be independently back gate biased to improve performance or reduce leakage depending upon the mode. Additionally, by reducing the total number of transistors in the WL driver (e.g., from 16 as seen in some prior art WL drivers to no more than 8), area may be improved. Furthermore, by employing only SG transistors (as opposed to a mixture of EG and SG transistors), manufacturability may be improved. Also disclosed herein are embodiments of a NVM structure (e.g., an MRAM structure) including a WL driver system with multiple instances of the disclosed WL driver. In some embodiments, the array can be partitioned into a pair of sub-arrays (with fewer columns in each sub-array and, thus, with shorter WLs in each sub-array) and the WL driver system can include pairs of WL drivers for corresponding rows in the sub-arrays, respectively, for improved slew.

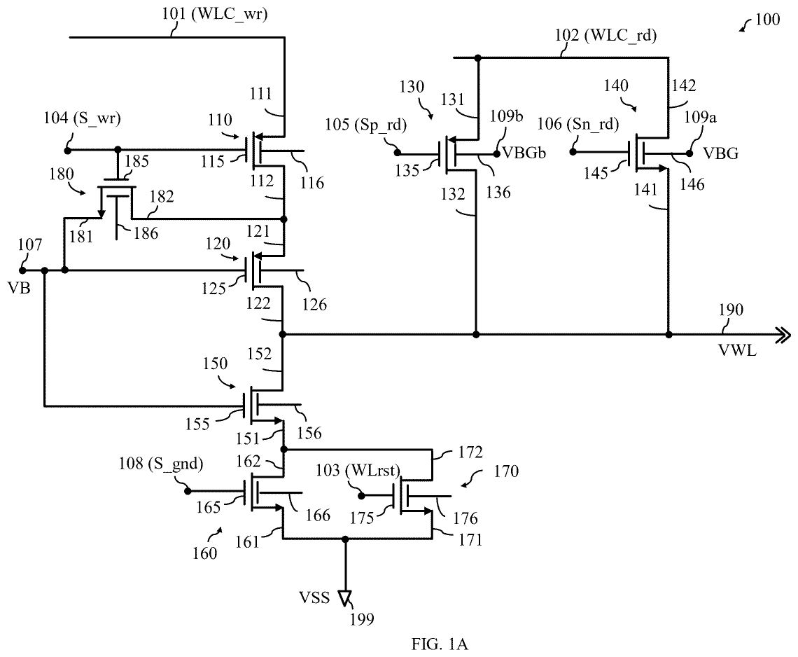

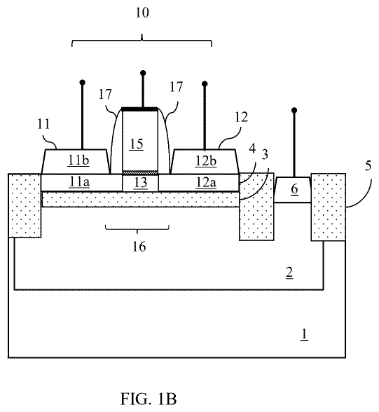

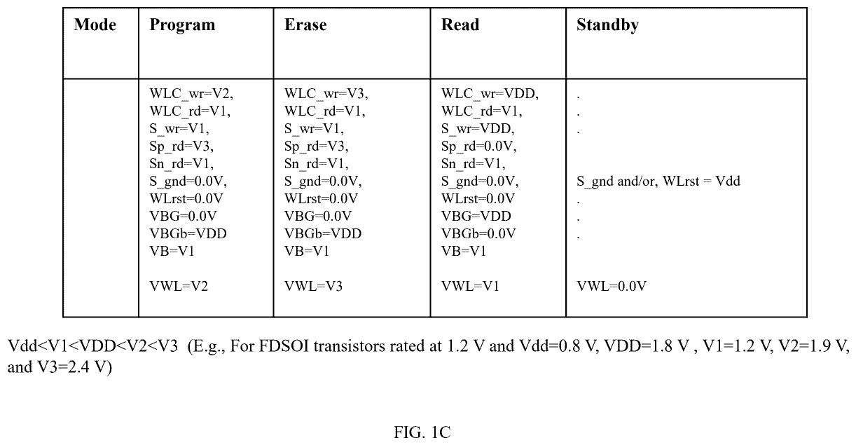

More particularly, FIG. 1A is a schematic diagram illustrating a disclosed embodiment of a WL driver 100 for a non-volatile memory (NVM) structure, such as a magnetic random access memory (MRAM) structure.

Those skilled in the art will recognize that a MRAM structure typically includes an array of bit cells (and, particularly, MRAM cells) arranged in columns and rows. All bit cells in a column can be connected to a bit line (BL)-source line (SL) pair for that column. All bit cells in a row can be connected to a WL for that row. Each MRAM cell (i.e., each bit cell) can include a magnetic tunnel junction (MTJ)-type programmable resistor. The MTJ-type programmable resistor is typically a back end of the line (BEOL) multi-layer structure. It can include a free ferromagnetic layer (also referred to as a free layer or switchable layer) and a fixed ferromagnetic layer (also referred to as a fixed layer or pinned layer) and a thin dielectric layer stacked between the free layer and the fixed layer. Each MRAM cell can further include an access transistor (e.g., an n-type field effect transistor (NFET)) connected in series with the MTJ-type programmable resistor between the SL and the BL for the column containing the bit cell. Specifically, the free layer of the MTJ-type programmable resistor can be electrically connected to the BL for the column and the source/drain regions of that access transistor can be electrically connected to the fixed layer of the MTJ-type programmable resistor and the SL for the column, respectively. Additionally, the gate of the access transistor can be electrically connected to the WL for the row.

Different memory operations directed to a selected bit cell in a given column and row in the MRAM structure (including a write operation, such as a program operation or an erase operation, and a read operation) can be performed by selectively applying specific bias conditions on the SL, BL and WL. For example, during an erase operation, high positive voltages can be applied to the SL and WL, whereas the BL can be discharged to ground (e.g., at 0V). In this case, current flow through the access transistor and programmable resistor to BL causes the free layer to switch to (or maintain) the anti-parallel resistance (RAP) state (also referred to as a high resistance state (HRS)), thereby storing a first logic value. During a program operation, high positive voltages can be applied to the BL and the WL and the SL can be connected to ground. In this case, current flow in the opposite direction through the programmable resistor and access transistor to the SL causes the free layer to switch to (or maintain) a parallel resistance (RP) state (also referred as a low resistance state (LRS)), thereby storing a second logic value opposite the first logic value. For example, the first logic value represented by the RAP/HRS could correspond to a logic value of “0” and the second logic value represented by the RP/LRS could correspond to a logic value of “1” or vice versa. For optimal performance, the positive voltage applied to the WL during an erase operation may be higher than the positive voltage applied to the WL during the program operation. During a read operation, positive voltages can be applied to the WL and BL, whereas the SL can be connected to ground. The positive voltage on the BL can be relatively high, but the positive voltage on the WL can be relatively low (as compared to that used during program and erase operations) to prevent unwanted state switching. A change in an electric parameter (e.g., current or voltage) on the BL can be detected (e.g., by a sense amplifier) during the read operation to determine whether the MTJ-type programmable resistor in the selected MRAM cell is RP/LRS (e.g., storing a logic value of “1”) or RAP/HRS (e.g., storing a logic value of “0”).

Referring again to FIG. 1A, disclosed herein are embodiments of a WL driver 100 configured to apply a word line voltage (VWL) at an appropriate positive voltage level to a WL of an NVM structure (e.g., an MRAM structure, as described) during the different memory operations (e.g., program, erase, and read) and to further ensure that VWL is at 0.0 volts (V) during any standby mode.

Specifically, WL driver 100 can include a first word line voltage (VWL) control node 101 (also referred to herein as a write VWL control node), which is connected to receive a variable write mode control voltage (WLC_wr) (e.g., from a voltage generation system for a row control block in peripheral circuitry of the NVM structure). WL driver 100 can also include second VWL control node 102 (also referred to herein as a read VWL control node), which is connected to receive a variable read mode control voltage (WLC_rd). The WL driver 100 can further include an output node 190, which outputs VWL to a WL.

WL driver 100 can further include multiple field effect transistors (FETs) and, in particular, can include no more than eight FETs, as discussed in greater detail below. Each of these FETs can have a relatively thin gate dielectric layer. That is, they can all be standard gate dielectric (SG) transistors. Each of the FETs can have the same voltage ratings, e.g., the same maximum gate-to-source voltage (VGSmax), maximum gate-to-drain voltage (VGDmax), and maximum drain-to-source voltage (VDS). These FETs can, for example, be implemented in an advanced semiconductor-on-insulator technology node. That is, they could be dual-gate fully-depleted semiconductor-on-insulator FETs (e.g., dual-gate fully-depleted silicon-on-insulator (FDSOI) FETs). Alternatively, the FETs could be dual-gate partially-depleted semiconductor-on-insulator FETs (e.g., dual-gate partially-depleted silicon-on-insulator (PDSOI) FETs). In an example embodiment, WL driver 100 can have FETs that are rated as 1.2-V FET. Furthermore, the NVM structure and WL drivers therein can employ two positive supply voltages, including a relatively high first positive supply voltage (VDD) of, for example, 1.8 V and a relatively low second positive supply voltage (Vdd) of, for example, 0.8 V.

FIG. 1B is a cross-section diagram illustrating an example of a structure of a FET 10 and, particularly, a dual-gated FDSOI FET that could be used for the FETs of WL driver 100. FET 10 can include a semiconductor substrate 1. Substrate 1 can be, for example, a monocrystalline silicon substrate or, alternatively, a monocrystalline substrate of any other suitable semiconductor material (e.g., silicon germanium, etc.). An insulator layer 3 can be on the top surface of semiconductor substrate 1. Insulator layer 3 can be, for example, a silicon dioxide layer or a layer of any other suitable insulator material. A semiconductor layer 4 can be on the top surface of insulator layer 3. Semiconductor layer 4 can be, for example, a monocrystalline silicon layer or a layer of any other suitable monocrystalline semiconductor material (e.g., silicon germanium, etc.).

Trench isolation regions 5 (e.g., shallow trench isolation (STI) structures) can define an active device region for FET 10 within semiconductor layer 4. Such STI structures can include, for example, one or more trenches patterned (e.g., lithographically) and etched so as to extend vertically from the top surface of semiconductor layer 4 to and, optionally, through insulator layer 3 and further so as to surround an active device region within semiconductor layer 4. The trench(es) can be filled with one or more layers of isolation materials (e.g., silicon dioxide, silicon nitride, silicon oxynitride, etc.), thereby forming the STI structures.

FET 10 can include, within its active device region, a channel region 13 positioned laterally between a source region 11 and a drain region 12. Those skilled in the art will recognize that, for an N-type field effect transistor (NFET), source/drain regions 11-12 can have N-type conductivity at a relatively high conductivity level (e.g., source/drain regions 11-12 can be N+source/drain regions). For a P-type field effect transistor (PFET), source/drain regions 11-12 can have P-type conductivity at a relative high conductivity level (e.g., source/drain regions 11-12 can be P+ source/drain regions). In any case, source/drain regions 11-12 can include lower source/drain portions 11a-12a including doped regions of semiconductor layer 4 on either side of channel region 13. Optionally, source/drain regions 11-12 can further include upper source/drain portions 11b-12b (also referred to herein as raised source/drain regions) above and immediately adjacent to lower source/drain portions 11a-12a, respectively. Upper source/drain portions 11b-12b can include epitaxially grown monocrystalline semiconductor layers (e.g., epitaxially grown silicon layers). Channel region 13 can be a portion of semiconductor layer 4, which is positioned laterally between the source/drain regions 11-12. Channel region 13 can be intrinsic (i.e., undoped) or doped so as to have an opposite type conductivity as compared to source/drain regions 11-12. That is, for an NFET, channel region 13 could have P-type conductivity at a relatively low conductivity level (e.g., channel region 13 could be a P-channel region). For a PFET, channel region 13 could have N-type conductivity at a relatively low conductivity level (e.g., channel region 13 could be an N-channel region).

FET 10 can further include a front gate 15 (also referred to herein as a primary gate) adjacent to (e.g., above, and immediately adjacent to) the active device region at channel region 13. Front gate 15 can include a gate dielectric layer (including one or more layers of gate dielectric material) immediately adjacent to channel region 13 and a gate conductor layer (including one or more layers of gate conductor material) on the gate dielectric layer. Front gate 15 could be any of a gate-first polysilicon gate structure, a gate-first high-K metal gate (HKMG) structure, a gate-last HKMG structure (also referred to as a replacement metal gate (RMG) structure), or any other suitable type of front gate structure. Gate sidewall spacers 17 can further be positioned laterally adjacent to sidewalls of front gate 15 to electrically isolate it from the adjacent source/drain regions 11-12. Front gate structures with gate sidewall spacers are well known in the art and, thus, the details thereof have been omitted from the specification in order to allow the reader to focus on the salient aspects of the disclosed embodiments.

FET 10 can further include a back gate 16 (also referred to herein as a secondary gate). Specifically, semiconductor substrate 1 can include a well region 2 therein. Well region 2 can be located at the top surface of semiconductor substrate 2 immediately adjacent insulator layer 3 and can further be aligned below the active device region. For purposes of this disclosure, a well region refers to a region of semiconductor material doped (e.g., via a dopant implantation process or any other suitable doping process) so as to have a particular conductivity type.

Those skilled in the art will recognize that one advantage of advanced semiconductor-on-insulator technology processing platforms is that FETs can be formed on an insulator layer above either a particular type of well region (e.g., an N-type well region (Nwell) or a P-type well region (Pwell)) in order to achieve different types of NFETs or PFETs with different threshold voltages (VTs). For example, for a super low threshold voltage (SLVT) or low threshold voltage (LVT) FET, an NFET can be formed above an Nwell and a PFET can be formed above a Pwell. For a regular threshold voltage (RVT) or high threshold voltage (HVT) FET, an NFET can be formed above a Pwell and a PFET can be formed above an Nwell. In WL driver 100, all FETs can be LVT or SLVT FETs. Whether the FETs are LVT or SLVT FETs will depend upon the design (e.g., device size, etc.) and process specifications (e.g., dopant concentrations, etc.).

Another advantage of advanced semiconductor-on-insulator technology processing platforms is that portions of the insulator layer and well regions aligned below a FET effectively form a back gate, which can be biased (referred to as back gate biasing or back-biasing) to fine tune the threshold voltage. Forward back-biasing (FBB) refers to applying a gate bias voltage to the back gate (particularly, to the well region thereof) to reduce the VT of the FET. Reverse back-biasing (RBB) refers specifically to applying a gate bias voltage to the back gate (particularly, to the well region thereof) to increase the VT of the FET, thereby decreasing the switching speed and reducing leakage current. Thus, in FET 10, portions of insulator layer 3 and well region 2 aligned below channel region 13 effectively form back gate 16. To facilitate back gate biasing, FET 10 can include a well contact region 6 (also referred to herein as a well tap). Specifically, the structure can further include a bulk region (also referred to as a hybrid region). This bulk region can be devoid of insulator layer 3 and instead can include well contact region 6 at the top surface of semiconductor substrate 1 immediately adjacent to well region 2 and electrically isolated from the active device region of by STI structures 5. Well contact region 6 can include, for example, an epitaxial monocrystalline semiconductor layer (e.g., an epitaxial silicon layer or an epitaxial layer of any other suitable semiconductor material), which is grown on the top surface of semiconductor substrate 1 immediately adjacent to well region 2 and either in situ doped or subsequently implanted so as to have the same type conductivity (e.g., N-type conductivity) but at a higher conductivity level. Alternatively, well contact region 6 could be a highly doped region within and at the top surface of well region 2. Given the above-described structure, front gate 15 and back gate 16 of FET 10 are independently biasable. That is, they can be biased with the same or different bias voltages.

Alternatively, any other suitable SG transistor structure, which is now known or later developed, could be employed for the various FETs of WL driver 100.

Referring again to FIG. 1A, WL driver 100 can include a first transistor 110 and a second transistor 120. First transistor 110 can include a first channel region positioned between a first source region 111 and a first drain region 112; and first front and back gates 115-116 adjacent to opposite surfaces of the first channel region. Second transistor 120 can include a second channel region positioned between a second source region 121 and a second drain region 122; and second front and back gates 125-126 adjacent to opposite surfaces of the second channel region. First transistor 110 and second transistor 120 can be PFETs, which are electrically connected in series between first VWL control node 101 and output node 190.

WL driver 100 can also include a third transistor 130 and a fourth transistor 140. Third transistor 130 can include a third channel region positioned between a third source region 131 and a third drain region 132; and third front and back gates 135-136 adjacent to opposite surfaces of the first channel region. Fourth transistor 140 can include a fourth channel region positioned between a fourth source region 141 and a fourth drain region 142; and fourth front and back gates 145-146 adjacent to opposite surfaces of the fourth channel region. Third transistor 130 and fourth transistor 140, which are a PFET and an NFET, respectively, can be electrically connected in parallel between second VWL control node 102 and the output node 190.

WL driver 100 can further include a fifth transistor 150 and a sixth transistor 160. Fifth transistor 150 can include a fifth channel region positioned between a fifth source region 151 and a fifth drain region 152; and fifth front and back gates 155-156 adjacent to opposite surfaces of the fifth channel region. Sixth transistor 160 can include a sixth channel region positioned between a sixth source region 161 and a sixth drain region 162; and sixth front and back gates 165-166 adjacent to opposite surfaces of the sixth channel region. Fifth transistor 150 and sixth transistor 160, which are NFETs, can be electrically connected in series between output node 190 and ground (VSS) 199 (at 0.0 V).

WL driver 100 can further include a seventh transistor 170. Seventh transistor 170 can include a seventh channel region positioned between a seventh source region 171 and a seventh drain region 172; and seventh front and back gates 175-176 adjacent to opposite surfaces of the seventh channel region. Seventh transistor 170, which is another NFET, can be electrically connected in parallel with sixth transistor 160 between fifth transistor 150 and ground (VSS) 199.

Optionally, WL driver 100 can include an eighth transistor 180. Eighth transistor 180 can include an eight channel region positioned between an eighth source region 181 and an eighth drain region 182; and eighth front and back gates 185-186 adjacent to opposite surfaces of the eighth channel region. Eighth transistor 180 can be yet another NFET. Eighth source/drain regions 181-182 can be electrically connected to a second front gate 125 of second transistor 120 and to the junction between first and second transistors 110 and 120. Additionally, eighth front gate 185 can be electrically connected to first front gate 115 of first transistor 110.

Additionally, within WL driver 100, first front gate 115 of first transistor 110 and, if present, eighth front gate 185 of eighth transistor 180 can be electrically connected to a write select signal node 104 to receive a write mode select signal (S_wr) (e.g., from select signal control logic in a row control block of peripheral circuitry of the NVM structure). Second front gate 125 of second transistor 120 and fifth front gate 155 of fifth transistor 150 can be electrically connected to a fixed bias voltage node 107 to receive a fixed gate bias voltage (VB) (e.g., from the voltage generation system). Third front gate 135 of third transistor 130 can be electrically connected to a first read select signal node 105 to receive a first read mode select signal (Sp_rd) (e.g., from the select signal control logic). Fourth front gate 145 of fourth transistor 140 can be electrically connected to a second read select signal node 106 to receive a second read mode select signal (Sn_rd) (e.g., from the select signal control logic). Sixth front gate 165 of sixth transistor 160 can be electrically connected to a ground select signal node 108 to receive ground select signal (S_gnd) (e.g., from the select signal control logic). Lastly, seventh front gate 175 of seventh transistor 170 can be electrically connected to a reset control node 103 to receive a word line reset control signal (WLrst) (e.g., from the voltage generation system).

In some embodiments, all back gates of all transistors in WL driver 100 can be connected to receive the same back gate bias voltage (e.g., can be connected to ground). In other embodiments, one or more of the back gates of the transistors in WL driver 100 could be connected to facilitate independent and selective operation-dependent back gate bias voltages to improve performance. For example, in some embodiments, all back gates 116, 126, 156, 166, 176, and 186, except for third back gate 136 of third transistor 130 and/or fourth back gate 146 of fourth transistor 140 can be electrically connected to ground 199 (VSS) (0.0 V), whereas third back gate 136 of third transistor 130 and/or fourth back gate 146 of fourth transistor 140 can be electrically connected to a discrete back gate bias node 109b and 109a. Back gate bias node 109a (and thereby fourth back gate 146) can be connected to receive a variable operation-dependent back gate bias voltage (VBG). Back gate bias node 109b (and thereby third back gate 136) could be connected to receive a different variable operation-depend back gate bias voltage (e.g., VBGb, which is inverted with respect to VBG). If VBG is employed for back gate biasing of fourth transistor 140, it can switch between 0.0 V when fourth transistor 140 (an NFET) is in an off state to minimize leakage and a positive supply voltage (e.g., VDD) when fourth transistor 140 is in an on state to increase drive current. Similarly, if VBGb is employed for back gate biasing of third transistor 130, it can switch between a positive supply voltage (e.g., VDD) when third transistor 130 (a PFET) is in an off state to minimize leakage and 0.0 V when third transistor 130 is in an on state to increase drive current.

WLC_wr, WLC_rd, WLrst, S_wr, Sp_rd, Sn_rd, S_gnd, and VBGb and/or VBG received at nodes 101, 102, 103, 104, 105, 106, 108 and 109b and/or 109a, respectively, can have voltage levels or logic values (as appropriate) that are operation-dependent in order to control the voltage level of VWL output by WL driver 100 at output node 190 depending upon whether WL driver 100 is operating in a program mode (one type of write), an erase operation (another type of write mode), a read mode, or a standby mode.

FIG. 1C is a table illustrating examples of mode-dependent bias conditions that can be employed on nodes 101-109 to achieve the desired voltage level for VWL at output node 190. For example, in the read mode, WLC_wr on first VWL control node 101, S_wr on write select signal node 104 can be at first positive supply voltage level (VDD) (e.g., VDD=1.8 V), WLC_rd on second VWL control node 102, and Sn_rd on second read select signal node 106 can be at a first voltage level (V1) that is less than VDD (e.g., V1=1.2 V). Additionally, during the read mode, Sp_rd on first read select signal node 105, S_gnd on ground select node 108, and WLrst on WL reset control node 103 can all be at ground 199 (VSS) (e.g., at 0.0 V). As mentioned above, VB at fixed bias voltage node 107 can be at a fixed voltage level. For example, VB can be at V1 (e.g., VB=V1=1.2 V). Optionally, VBG on back gate bias node 109a (and thereby on fourth back gate 146 of fourth transistor 140) can be at VDD (e.g., VBG=VDD=1.8 V) and/or VBGb on back gate bias node 109b (and thereby on third back gate 136 of third transistor 130) can be at 0.0 V.

Thus, in this read mode, first transistor 110 is in an off-state, preventing VWL at output node 190 from being pulled-up to WLC_wr therethrough. Additionally, fifth transistor 150 and sixth transistor 160 are in off-states, thereby preventing VWL on output node 190 from being pull-down to ground therethrough. However, both third transistor 130 and fourth transistor 140 will both be in on-states. Thus, both third transistor 130 and fourth transistor 140 act to pull VWL on output node 190 up to WLC_rd, which, as mentioned above, is at V1 (e.g., 1.2 V) during the read mode. Additionally, if as mentioned above VBG at VDD is applied through back gate bias node 109a to fourth back gate 146 of fourth transistor 140 (an NFET), then drive current therethrough can be increased as compared to when no back gate or zero back gate biasing is employed for improved performance. Similarly, if, as mentioned above VBGb at 0.0 V is applied through back gate bias node 109b to third back gate 136 of third transistor 130 (a PFET), then drive current therethrough can be increased as compared to when no back gate is employed for improved performance.

In the program mode, WLC_rd on second VWL control node 102, S_wr on write select signal node 104, and Sn_rd on second read select signal node 106 are at V1 (e.g., 1.2 V). Furthermore, WLC_wr on first VWL control node 101 is at a second voltage level (V2) that is greater than V1 (e.g., V2=1.9 V), and Sp_rd at first read select signal node 105 is at a third voltage level (V3) that is greater than V1 (e.g., V3=2.4 V). Additionally, during the program mode, S_gnd on ground select node 108 and WLrst on WL reset control node 103 can be at ground 199 (VSS or 0.0 V). As mentioned above, VB at fixed bias voltage node 107 can be at a fixed gate bias voltage level (e.g., VB=V1=1.2 V). Optionally, during the program mode, VBG on back gate bias node 109a can be at ground (e.g., VBG=VSS=0V) and/or VBGb on back gate bias node 109b can be at VDD (e.g., VBGb=VDD=1.8 V).

Thus, in this program mode, third transistor 130 and fourth transistor 140 are in off-states, thereby preventing VWL on output node 190 from being pulled up to WLC_rd therethrough. Additionally, fifth transistor 150 and sixth transistor 160 are in off-states, preventing VWL at output node 190 from being pull-down to ground therethrough. However, both first transistor 110 and second transistor 120 will both be in on-states. Thus, the first and second transistors 110-120 act to pull VWL on output node 190 up to WLC_wr, which, as mentioned above, is at V2 (e.g., V2=1.9 V), during the program mode. Additionally, if, as mentioned above, VBG of 0.0 V is applied through back gate bias node 109a to fourth back gate 146 of fourth transistor 140 (an NFET), then leakage current can be decreased as compared to when no back gate biasing is employed. Similarly, if, as mentioned above, VBGb of VDD is applied through back gate bias node 109b to third back gate 136 of third transistor 130 (a PFET), then leakage current can be decreased as compared to when no back gate biasing is employed.

In the erase mode, WLC_rd on second VWL control node 102, S_wr on write select signal node 104 and Sn_rd on second read select signal node 106 are at V1 (e.g., 1.2 V). Furthermore, WLC_wr on first VWL control node 101 and Sp_rd on first read select signal node 105 are at V3 (e.g., at 2.4 V). Additionally, during the erase mode, S_gnd on ground select node 108, and WLrst on WL reset control node 103 can be at ground 199 (VSS). As mentioned above, VB at fixed bias voltage node 107 can be at a fixed gate bias voltage level (e.g., VB=V1=1.2 V). Optionally, during the erase mode, VBG on back gate bias node 109a can be at ground (e.g., VBG=VSS=0.0 V) and/or VBGb on back gate bias node 109b can be at VDD (e.g., VBGb=VDD=1.8 V).

Thus, in this erase mode, third transistor 130 and fourth transistor 140 are in off-states, thereby preventing VWL on output node 190 from being pulled up to WLC_rd therethrough. Additionally, fifth transistor 150 and sixth transistor 160 are in off-states, preventing VWL at output node 190 from being pull-down to ground therethrough. However, both first transistor 110 and second transistor 120 will both be in on-states. Thus, the first and second transistors 110-120 act to pull VWL on output node 190 up to WLC_wr, which, as mentioned above, is at V3 (e.g., V3=2.4 V), during the erase mode. Additionally, if, as mentioned above, VBG of 0.0 V is applied through back gate bias node 109a to fourth back gate 146 of fourth transistor 140, leakage current can be decreased as compared to when no back gate biasing is employed. Similarly, if, as mentioned above, VBGb of VDD is applied through back gate bias node 109b to third back gate 136 of third transistor 130 (a PFET), then leakage current can be decreased as compared to when no back gate biasing is employed.

In any standby mode (i.e., when WL driver 100 is not in a program mode, an erase mode, or a read mode) WLC_wr, WLC_rd, WLrst, S_wr, Sp_rd, Sn_rd, S_gnd, and VBG received at nodes 101, 102, 103, 104, 105, 106, 108 and 109, respectively, can have voltage levels or logic values (as appropriate) to ensure that VWL on output node 190 is at ground (i.e., at 0V). Generally, in a standby mode, at least first transistor 110, third transistor 130 and fourth transistor 140 will be in off-states, thereby preventing VWL on output node 190 from being pulled-up. Furthermore, fifth transistor 150 will be in an on-state and at least one of S_gnd or WLrst will be at the second positive supply voltage level (Vdd, for example, at 0.8 V) so sixth transistor 160 and/or seventh transistor 170 will also be in an on-state, thereby allowing VWL on output node 190 to be pulled-down to ground. If VBG on back gate bias node 109a is also at ground and/or VBGb on back gate bias node 109b is at VDD during the standby mode, leakage current third transistor 130 and/or fourth transistor 140, respectively, can be reduced as compared to if no back gate biasing is employed.

It should be noted that eighth transistor 180 is included within WL driver 100 as a protection device under certain biasing conditions. For example, during a particular standby mode, first transistor 110 and second transistor 120 could be off with S_wr at V2 and VB at V1. In this case, the node at the junction between first drain region 112 of first transistor 110 and second source region 121 of second transistor 120 will otherwise be left floating and able to settle at a low-level voltage that results in a safe operating area (SOA) violation. By including eighth transistor 180, under the same conditions, the node at the junction between first drain region 112 and second source region 121 will be maintained at a mid-level voltage to avoid the SOA violation.

Consequently, none of the eight transistors 110-180 of WL driver 100 are at risk of safe operation area (SOA) violations (i.e., violations of VGSmax, VGDmax or VDSmax) during any of the various modes of operation described above.

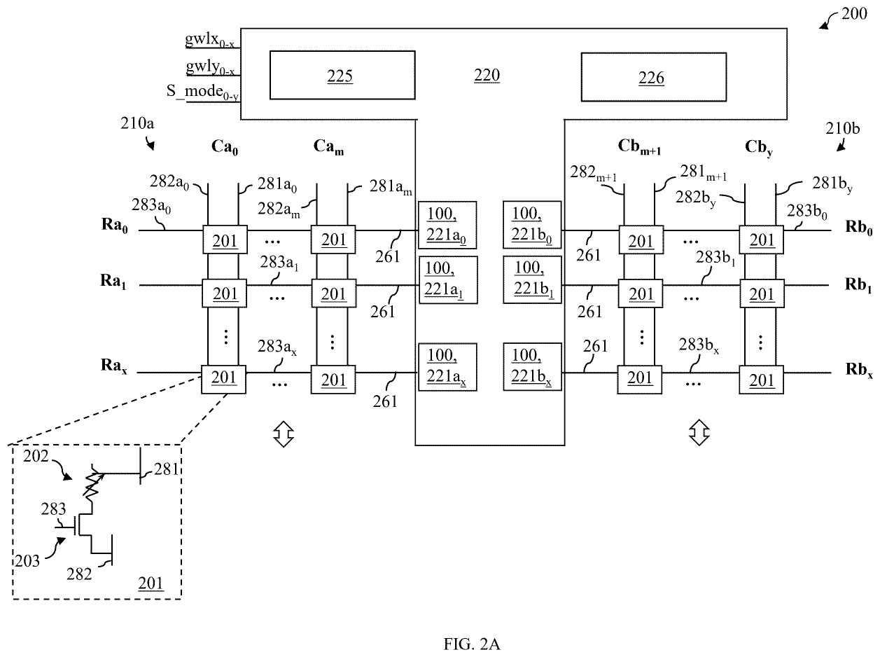

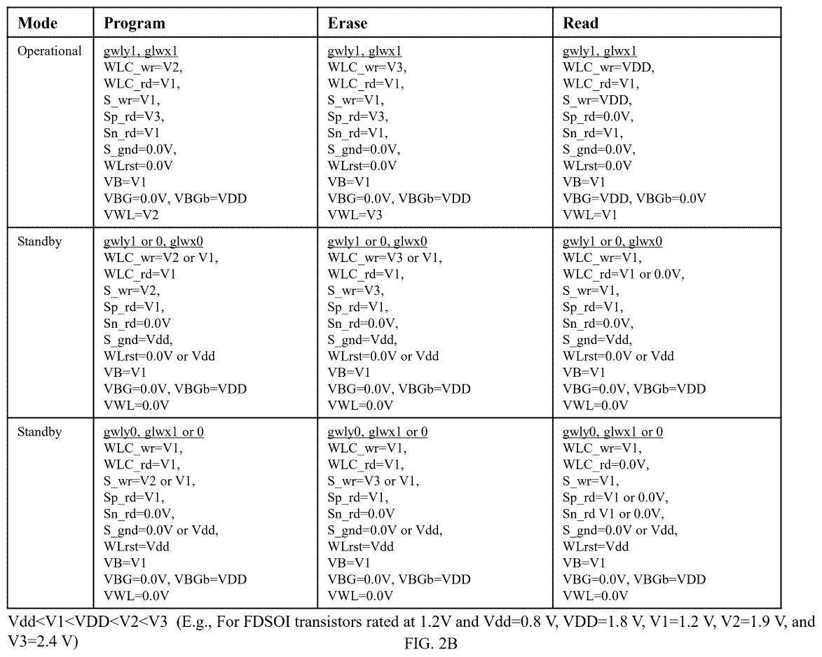

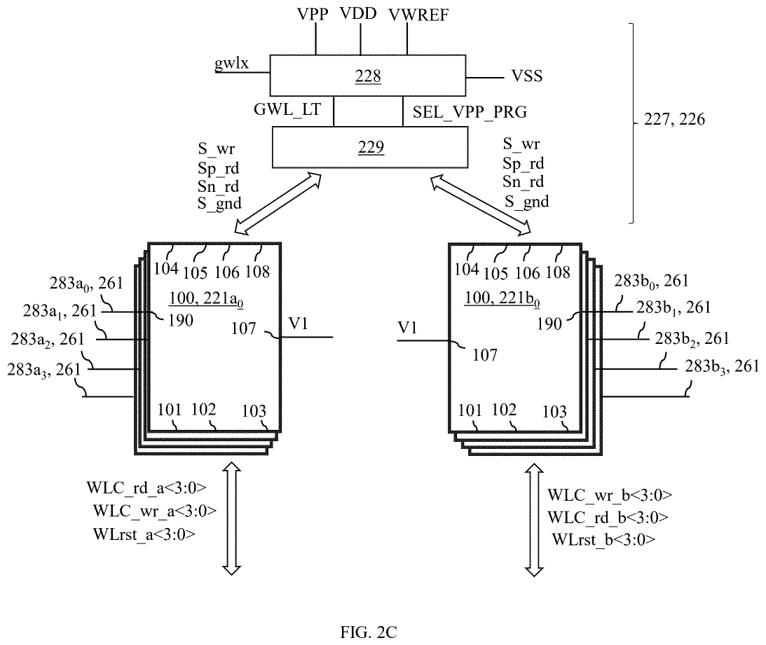

Referring to FIG. 2A, also disclosed herein are embodiments of a NVM structure 200 (hereinafter referred to as structure 200). Structure 200 can, for example, be a MRAM structure. Structure 200 can include multiple instances of WL driver 100 of FIG. 1A, described in detail above. Specifically, structure 200 can include an array of bit cells 201. Optionally, as illustrated, the array of bit cells 201 can be partitioned into a first sub-array 210a (also referred to herein as a left-side sub-array or a top sub-array) and a second sub-array 210b (also referred to herein as a right-side sub-array or a bottom sub-array). Each sub-array 210a and 210b can have the same total number of rows (e.g., see rows Ra0-Rax in first sub-array 210a and rows Rb0-Rbx in second sub-array 210b). First sub-array 210a can include some number of columns C0-Cm and second sub-array 210b can include some number of columns Cm+1-Cy. In some embodiments, each sub-array 210a and 210b can have the same number of number of columns equal to one-half of the total number of columns in the array (i.e., ½ (y+1)). In other embodiments, first sub-array 210a and second sub-array 210b could have different numbers of columns.

For each sub-array 210a and 210b, structure 200 can further includes bit lines (BLs) for the columns (e.g., see BLs 281a₀-281aₘ in first sub-array 210a and BLs 281bₘ₊₁-281b_{y} in second sub-array 210b), source lines (SLs) for the columns (e.g., see SLs 282a₀-282aₘ in first sub-array 210a and SLs 282bₘ₊₁-282b_{y} in second sub-array 210b)), and WLs for the rows (e.g., see WLs 283a₀-283aₓ in first sub-array 210a and WLs 283b₀-283bₓ in second sub-array 210b). All bit cells 201 in a column can be connected to a bit line (BL)-source line (SL) pair for that column. All bit cells 201 in a row can be connected to a WL for that row. Each bit cell 201 in a given column and row can include a programmable resistor 202 and an access transistor 203 (e.g., an NFET) electrically connected in series between a BL-SL pair for the column and the gate of access transistor 203 can further be electrically connected to a WL for the row. Since the array is partitioned into a pair of sub-arrays by columns, as mentioned above, it should be understood that the BLs/SLs in each sub-array will be the same length as if the array was not partitioned. However, the WLs in each sub-array will be shorter in length that if the array was not partitioned. In any case, each bit cell 201 can, for example, be an MRAM cell in which the programmable resistor is an MTJ-type programmable resistor. As mentioned above, an MTJ-type programmable resistor can be a BEOL multi-layer structure. It can include a free ferromagnetic layer, a fixed ferromagnetic layer, and a thin dielectric layer stacked between the free layer and the fixed layer. In such an MRAM cell, the free layer of the MTJ-type programmable resistor can be electrically connected to the BL for the column and the source/drain regions of that access transistor can be electrically connected to the fixed layer of the MTJ-type programmable resistor and the SL for the column, respectively. Additionally, the gate of the access transistor can be electrically connected to the WL for the row.

Structure 200 can further include a controller and, in communication with the controller, peripheral circuitry connected to the BLs, SLs and WLs for the different sub-arrays 210a and 210b and configured to selectively establish specific bias conditions on each BL, SL, and WL in each sub-array in response to control signals from the controller to facilitate the performance of a write operation (e.g., program or erase operations) or read operation in a selected bit cell while maintaining other bit cells in a standby mode. This peripheral circuitry can also include a sense circuit configured to detect a change in an electric parameter (e.g., current or voltage) on a BL connected to a selected bit cell during a read operation in order to determine whether MTJ-type programmable resistor in the selected MRAM cell is RAP/HRS (storing a first logic value) or RP/LRS (storing a second logic value). It should be noted that the first logic value represented by the RAP/HRS could correspond to a logic value of “0” and the second logic value represented by the RP/LRS could correspond to a logic value of “1” or vice versa. Generally, peripheral circuitry for NVM structures is known in the art. Thus, other than the detailed discussion below regarding the WL driver system 220, such peripheral circuitry is omitted from the figures and specification in order to allow the reader to focus on the salient aspects of the disclosed embodiments.

More specifically, peripheral circuitry of structure 200 can include a WL driver system 220. WL driver system 220 can include multiple WL drivers, which are configured as described in detail above and illustrated in FIG. 1A. In embodiments where the array of bit cells 201 is not partitioned into sub-arrays, structure 200 could have one WL driver for each WL (not shown).

In other embodiments where the array of bit cells 201 is partitioned into sub-arrays 210a-210b, as illustrated, structure 200 can include pairs of WL drivers for corresponding rows in the sub-arrays 210a and 210b. For example, see WL drivers 221a₀ and 221b₀ for WLs 283a₀ and 283b₀ of corresponding rows Ra₀ and Rb₀ for sub-arrays 210a and 210b, respectively; see WL drivers 221a₁ and 221b₁ for WLs 283a₁ and 283b₁ of corresponding rows Ra₁ and Rb₁ for sub-arrays 210a and 210b, respectively; and so on to WL drivers 221aₓ and 221bₓ for WLs 283aₓ and 283bₓ of corresponding rows Raₓ and Rbₓ for sub-arrays 210a and 210b, respectively. In this case, each of the WL drivers 221a and 221b in a given pair of WL drivers for a corresponding row in the sub-arrays 210a-b can be configured as described in detail above and illustrated in FIG. 1A and can have output nodes 190 connected to proximal ends 261 of the WLs 283 for that row. By partitioning a large array into sub-arrays, as described, the relatively long WLs for the row in the array are also each partitioned into a pair of discrete shorter WLs 283a and 283b for corresponding rows in the sub-arrays. Since each of these shorter WLs 283a and 283b is connected to a corresponding WL driver, slew and, particularly, the rate at which it takes for the two shorter WLs 283a and 283b to become fully charged to the desired VWL as opposed to the rate at which it would take a single longer WL to become fully charged to the desired VWL can be improved and, as a result, cycle time can also be improved.

WL driver system 220 can further include a voltage generation system 225 and control logic 226, which in combination are configured to generate and output a set of signals to each WL driver in the structure. In any case, as discussed above with regard to WL driver 100 of FIG. 1A, the set of signals can include WLC_wr, WLC_rd, WLrst, S_wr, Sp_rd, Sn_rd, VB, S_gnd, and VBG applied to nodes 101, 102, 103, 104, 105, 106, 107, 108, and 109, respectively. Except for the voltage level of VB (which is fixed), the voltage levels or logic values (as appropriate) of the other signals in the set and received by WL driver(s) connected to a corresponding WL will be operation-dependent (i.e., will vary depending upon whether the WL driver(s) are operating in the program mode, the erase operation, the read mode, or a standby mode) to control the voltage level of VWL, which is output by the WL driver(s) connected to a corresponding WL.

In some embodiments, WL driver system 220 can receive (e.g., from the controller) various row-specific control signals including a mode select signal (S_mode₀₋ₓ) and a pair of global word line control signals (gwlx₀₋ₓ and gwly₀₋ₓ) to establish the set of signals to be supplied to the pairs of WL drivers 221a₀-221b₀, 221a₁-221b₁, . . . 221aₓ-221bₓ for the pair of corresponding rows Ra₀-Rb₀, Ra₁-Rb₁, . . . Raₓ-Rbₓ in the sub-arrays 210a and 210b, respectively. S-mode₀₋ₓ for a given pair of corresponding rows can be the mode (e.g., program, erase, read, or standby). Gwlx₀₋ₓ and gwly₀₋ₓ for the given pair of corresponding rows can each be either a logic “1” or a logic “0.” Depending upon the combination of S_mode, gwlx and gwly for a given pair of corresponding rows in the sub-arrays 210a-210b, control logic 226 can output different sets of signals to the pair of WL drivers for that given pair of corresponding rows. FIG. 2B is a table illustrating different sets of signals for controlling a pair of WL drivers for a row as a function of different values for S_mode, gwlx and gwly.

FIG. 2C is a block diagram illustrating an example of a portion 227 of control logic 226. This portion 227 of control logic 226 can include an up-level translator 228 and select signal control logic 229. Up-level translator 228 can be connected between VDD and ground and can further be connected to receive glwx, VWREF and VPP. In response, up-level translator 228 can output a pair of signals include gwl_lt and sel_vpp_prg. Select signal control logic 229 can receive gwl_lt and sel_vpp_prg and in response can output a set of select signals include S_wr, Sp_rd, Sn_rd, and S_gnd, as discussed above. The same row-specific set of select signals can be received by both WL drivers in the pairs. Additionally, as illustrated in FIG. 2C, in some embodiments multiple pairs of WL drivers can share the same select signal control logic 229. For example, four pairs of WL drivers 221a₀-221b₀, 221a₁-221b₁, 221a₂-221b₂, and 221a₃-221b₃ for four pairs of corresponding rows Ra₀-Rb₀, Ra₁-Rb₁, Ra₂-Rb₂, and Ra₃-Rb₃ could be connected to control logic 229 to each receive row-specific signals for WLC_wr_a<3:0>-WLC_wr_b<3:0>, WLC_rd_a<3:0>-WLC_rd_b<3:0>, and WLrst_a<3:0>-WLrst_b<3:0>, respectively. It should be understood that, while such signals (WLC_wr, WLC_rd, and WLrst) may vary from row-to-row in the same sub-array, they will be the same for corresponding rows of different sub-arrays.

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first word line voltage (VWL) control node;
a second VWL control node;
an output node;
a first transistor and a second transistor connected in series between the first VWL control node and the output node; and
a third transistor and a fourth transistor connected in parallel between the second VWL control node and the output node, wherein the first transistor, the second transistor and the third transistor have a first type conductivity and the fourth transistor has a second type conductivity different from the first type conductivity.

2. The structure of claim 1, further comprising: a fifth transistor and a sixth transistor connected in series between the output node and ground.

3. The structure of claim 2,
wherein the first transistor, the second transistor, and the third transistor include P-type field effect transistors, and
wherein the fourth transistor, the fifth transistor, and the sixth transistor are N-type field effect transistors.

4. The structure of claim 3,
wherein the first VWL control node is connected to receive a write mode control voltage,
wherein the second VWL control node is connected to receive a read mode control voltage,
wherein a first gate of the first transistor is connected to receive a write mode select signal,
wherein a second gate of the second transistor is connected to receive a fixed gate bias voltage,
wherein a third gate of the third transistor is connected to receive a first read mode select signal,
wherein a fourth gate of the fourth transistor is connected to receive a second read mode select signal,
wherein a fifth gate of the fifth transistor is connected to receive the fixed gate bias voltage, and
wherein a sixth gate of the sixth transistor is connected to receive a ground select signal.

5. The structure of claim 4, wherein, in a read mode, the write mode control voltage and the write mode select signal are at a positive supply voltage level, the read mode control voltage, and the second read mode select signal are at a first voltage level that is less than the positive supply voltage level, and the first read mode select signal is at ground.

6. The structure of claim 5, wherein, in a program mode, the read mode control voltage, the write mode select signal, and the second read mode select signal are at the first voltage level, the write mode control voltage is at a second voltage level that is greater than the first voltage level, and the first read mode select signal is at a third voltage level that is greater than the second voltage level.

7. The structure of claim 6, wherein, in an erase mode, the read mode control voltage, the write mode select signal and the second read mode select signal are at the first voltage level, and the write mode control voltage and the first read mode select signal are at the third voltage level.

8. The structure of claim 7, wherein a word line voltage output at the output node is mode-dependent and variable between 0.0 V, the first voltage level, the second voltage level, and the third voltage level.

9. The structure of claim 4, wherein at least one of the third transistor and the fourth transistor includes a back gate biasable during a read mode to increase drive current and differently biasable during any of a program mode, an erase mode, and a standby mode to limit leakage current.

10. The structure of claim 4, further comprising:
a seventh transistor connected in parallel with the sixth transistor between the fifth transistor and ground, wherein a seventh gate of the seventh transistor is connected to receive a word line reset signal; and
an eighth transistor connected between the second gate of the second transistor and a junction between the first transistor and the second transistor, wherein the eighth transistor has an eighth gate connected to the first gate of the first transistor, wherein the seventh transistor and the eight transistor are N-type field effect transistors.

11. A structure comprising:
a first word line voltage (VWL) control node connected to receive a write mode voltage signal;
a second VWL control node connected to receive a read mode voltage signal;
an output node;
a first transistor and a second transistor connected in series between the first VWL control node and the output node;
a third transistor and a fourth transistor connected in parallel between the second VWL control node and the output node;
a fifth transistor and a sixth transistor connected in series between the output node and ground;
a seventh transistor connected in parallel with the sixth transistor between the fifth transistor and ground; and
an eighth transistor connected between a gate of the second transistor and a junction between the first transistor and the second transistor, wherein gates of the first transistor and the eighth transistor are connected,
wherein the first transistor, the second transistor, and the third transistor are P-type field effect transistors, and
wherein the fourth transistor, the fifth transistor, the sixth transistor, the seventh transistor, and the eighth transistor are N-type field effect transistors.

12. A structure comprising:
an array of bit cells in columns and rows;
word lines for the rows, respectively; and
a word line driver system including: word line drivers connected to the word lines,
wherein each word line driver includes:
a first word line voltage (VWL) control node;
a second VWL control node;
an output node connected to an end of a word line;
a first transistor and a second transistor connected in series between the first VWL control node and the output node; and
a third transistor and a fourth transistor connected in parallel between the second VWL control node and the output node, and
wherein the first transistor, the second transistor and the third transistor have a first type conductivity and the fourth transistor has a second type conductivity different from the first type conductivity.

13. The structure of claim 12, wherein the bit cells include magnetic random access memory (MRAM) cells.

14. The structure of claim 12, wherein each word line driver further includes:
a fifth transistor and a sixth transistor connected in series between the output node and ground;
a seventh transistor connected in parallel with the sixth transistor between the fifth transistor and ground; and
an eighth transistor connected between a gate of the second transistor and a junction between the first transistor and the second transistor,
wherein the first transistor, the second transistor, and the third transistor are P-type field effect transistors, and
wherein the fourth transistor, the fifth transistor, the sixth transistor, the seventh transistor, and the eighth transistor are N-type field effect transistors.

15. The structure of claim 14,
wherein the word line driver system includes pairs of the word line drivers for corresponding rows in pairs of sub-arrays,
wherein the word line driver system further includes control logic configured to apply a same set of signals to both word line drivers in at least one pair of the word line drivers and,
wherein the set of signals includes:
a write mode control voltage received at the first VWL control node in each of the word line drivers,
a read mode control voltage received at the second VWL control node in each of the word line drivers,
a write mode select signal received at a first gate of the first transistor in each of the word line drivers,
a fixed gate bias voltage received at a second gate of the second transistor in each of the word line drivers,
a first read mode select signal received at a third gate of the third transistor in each of the word line drivers,
a second read mode select signal received at a fourth gate of the fourth transistor in each of the word line drivers,
the fixed gate bias voltage received at a fifth gate of the fifth transistor in each of the word line drivers,
a ground select signal received at a sixth gate of the sixth transistor in each of the word line drivers, and
a word line reset control signal received at a seventh gate of the seventh transistor in each of the word line drivers.

16. The structure of claim 15, wherein, in a read mode, the write mode control voltage and the write mode select signal are at a positive supply voltage level, the read mode control voltage and the second read mode select signal are at a first voltage level that is less than the positive supply voltage level, and the first read mode select signal is at ground.

17. The structure of claim 16, wherein, in a program mode, the read mode control voltage, the write mode select signal, and the second read mode select signal are at the first voltage level, the write mode control voltage is at a second voltage level that is greater than the first voltage level, and the first read mode select signal is at a third voltage level that is greater than the second voltage level.

18. The structure of claim 17, wherein, in an erase mode, the read mode control voltage, the write mode select signal and the second read mode select signal are at the first voltage level, and the write mode control voltage and the first read mode select signal are at the third voltage level.

19. The structure of claim 18, wherein a word line voltage output at the output node is mode-dependent and variable between 0.0 V, the first voltage level, the second voltage level, and the third voltage level.

20. The structure of claim 18, wherein, within each word line driver, at least one of the third transistor and the fourth transistor has a back gate biasable during the read mode to increase drive current and differently biasable during any of a program mode, an erase mode, and a standby mode to limit leakage current.
